(19) United States
(12) Patent Application Publication
(10) Pub. No.: US 2007/0030733 A1
(43) Pub. Date: Feb. 8, 2007

(54) Faulty storage area marking and accessing method and system

(75) Inventors: Yi-Hung Shen, Hsin-Chu (TW); Peng-Chao Wang, Hsin-Chu (TW); Yu-Tsun Hsieh, Hsin-Chu (TW)

Correspondence Address: EDWARDS & ANGELL, LLP, P.O. BOX 55874, BOSTON, MA, 02205, US

(73) Assignee: RDC Semiconductor Co., Ltd., Hsin Chu (TW)

(21) Appl. No.: 11/500,574

(22) Filed: Aug. 7, 2006

Related U.S. Application Data
(63) Continuation-in-part of application No. 11/267,115, filed on Nov. 3, 2005.

(30) Foreign Application Priority Data
Aug. 8, 2005 (TW) 094126687

(51) Int. Cl. G11C 16/06

(52) U.S. Cl. 365/185.09

(57) ABSTRACT

A faulty storage area marking and accessing method and system applicable to a data storage unit (e.g. an embedded memory integrated in a SoC) having a plurality of storage areas, for providing the data storage unit with an automatic faulty storage area marking function for access control, so as to inspect and identify faulty storage areas and operable storage areas of the data storage unit. Therefore, when a client unit intends to access the data storage unit, the faulty storage areas are avoided being accessed and only the operable storage areas are accessed. This feature allows the SoC to still operate properly even if the embedded memory thereof has faulty storage areas, without having to replace the entire SoC.

### CROSS-REFERENCE TO RELATED APPLICATION

This application is a continuation-in-part of copending application Ser. No. 11/267,115 filed on Nov. 3, 2005, the disclosure of which is expressly incorporated herein by reference.

### BACKGROUND OF THE INVENTION

1. Field of the Invention

The present invention relates to computer system technologies, and more particularly, to a faulty storage area marking and accessing method and system, for use with a data storage unit having a plurality of storage areas so as to inspect and identify faulty storage areas and operable storage areas of the data storage unit such that only the operable storage areas are allowed to be accessed.

2. Description of Related Art

A system on chip (SoC) is a full functional chip module, which integrates all functional components, such as a central processing unit (CPU), a memory unit, an input/output interface unit and other auxiliary circuit units, of a microcomputer system into a single chip. The SoC allows various operations of the microcomputer system to be accomplished by the single chip. The functional components integrated in the SoC are referred to as embedded components, for example, a memory in the SoC is named an embedded memory.

However, some of storage areas of the embedded memory in the SoC may become 4 faulty and can no longer store data, thereby leading to a reliability issue if data access is performed through the faulty storage areas of the embedded memory. As the embedded memory is integrated in the SoC, it cannot be easily replaced if having any faulty storage areas. Therefore, if any storage area of the embedded memory is faulty, the entire chip has to be replaced even though other components such as CPU, input/output interface unit and auxiliary circuit units still function properly, thereby not favorable for the economical concern.

To address the aforementioned problem, a circuit technology for self-repairing faulty storage areas of a memory has been proposed in U.S. Patent Publication Nos. 20040225912 and 20030196143.

However, implementation of the above circuit technology for self-repairing faulty storage areas requires complicated circuits and additional circuit layout space and is not cost-effective.

Moreover, as the Deep Sub-Micron (DSM) technology is being rapidly developed, more and more electronic circuits are allowed to be integrated in a single integrated circuit. The size of embedded memory integrated in an SoC becomes larger and larger and the chance to have faulty storage area in the embedded memory in the SoC is also increasing.

Therefore, the problem to be solved here is to provide a faulty storage area marking and accessing method and system, which can overcome the foregoing drawbacks.

### SUMMARY OF THE INVENTION

In light of the above-mentioned drawbacks of the prior art, it is a primary objective of the present invention to provide a faulty storage area marking and accessing method and system, which can automatically inspect and mark faulty storage areas of a data storage unit e.g. an embedded memory integrated in a SoC, such that the faulty storage areas are avoided being accessed, and only operable storage areas of the embedded memory are accessed, thereby allowing the SoC to still operate properly even if the embedded memory has the faulty storage areas, without having to replace the entire SoC.

It is another objective of the present invention to provide a faulty storage area marking and accessing method and system, which can be implemented without using complicated circuits and additional circuit layout space, thereby more cost-effective than the prior art.

In order to achieve the above and other objectives, the present invention proposes a faulty storage area marking and accessing method and system for use with a data storage unit having a plurality of storage areas, such as an embedded memory integrated in a SoC (e.g. a cache memory), an external memory (e.g. a flash memory) or any other data storage device. The faulty storage area marking and accessing method and system provide the data storage unit with an automatic faulty storage area marking function for access control, such that when a client unit (e.g. an internal microprocessor) wishes to access the data storage unit, any inspected and marked faulty storage areas are avoided being accesses, and only operable storage areas of the data storage unit are accessed.

The faulty storage area marking and accessing method of the present invention includes the steps of: (1) performing a storage area inspecting process on the data storage unit to inspect whether each of the storage areas is in an operable or faulty status to identify operable storage areas and faulty storage areas of the data storage unit in response to receiving an inspecting startup event; (2) recording the inspected operable or faulty status of the storage areas of the data storage unit, and assigning addresses of the faulty storage areas to addresses of the operable storage areas of the data storage unit in accordance with a predefined address assigning rule; (3) inspecting whether access addresses contained in a request message issued by a client unit to the data storage unit match any address corresponding to the faulty storage areas when the client unit issues the request message to the data storage unit, and if at least one of the access addresses is inspected to correspond to the faulty storage areas, changing at least one access address to at least one of the addresses of the operable storage areas in accordance with the predefined address assigning rule; and (4) accessing the operable storage areas of the data storage unit in place of the faulty storage areas.

The faulty storage area marking and accessing system of the present invention includes: a storage area inspecting module for performing a storage area inspecting process on the data storage unit to inspect whether each of the storage areas is in an operable or faulty status to identify faulty storage areas and operable storage areas of the data storage unit in response to an inspecting startup event; a storage area recording module for recording the inspected operable or faulty status of the storage areas of the data storage unit, and assigning addresses of the faulty storage areas to addresses of the operable storage areas in accordance with a predefined address assigning rule; and an access managing and controlling module for receiving a request message containing access addresses issued by a client unit to the data storage unit and inspecting whether the access addresses of the request message match any address corresponding to the faulty storage areas, wherein if at least one of the access addresses is inspected to correspond to the faulty storage areas, the access managing and controlling module changes the at least one access address to at least one of the addresses of the operable storage areas in accordance with the predefined address assigning rule, so as to allow the operable storage areas of the data storage unit to be accessed in place of the faulty storage areas.

By applying the faulty storage area marking and accessing method and system of the present invention to the data storage unit (such as an embedded memory integrated in a SoC), the storage area inspecting process is performed on the data storage unit to identify the operable storage areas and faulty storage areas of the data storage unit. Thereby, when a client unit wishes to access the data storage unit, the faulty storage areas are avoided being accessed and only the operable storage areas are accessed. This feature allows the SoC to still operate properly even if the embedded memory thereof has faulty storage areas, without having to replace the entire SoC.

### BRIEF DESCRIPTION OF DRAWINGS

The invention can be more filly understood by reading the following detailed description of the preferred embodiments, with reference made to the accompanying drawings, wherein:

FIG. 1 is a schematic block diagram of basic architecture of a faulty storage area marking and accessing system according to the present invention; and

FIG. 2 is a schematic diagram showing an address mapping table for mapping addresses of faulty storage areas to addresses of operable storage areas, used by the faulty storage area marking and accessing system according to the present invention.

### DETAILED DESCRIPTION OF PREFERRED EMBODIMENTS

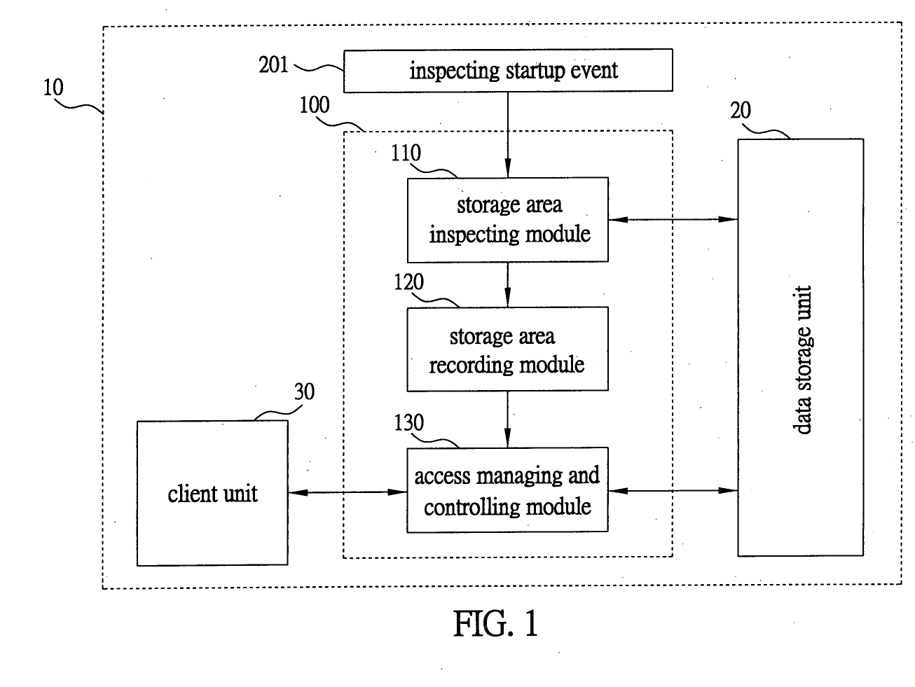

FIG. 1 is a schematic block diagram of basic architecture of a faulty storage area marking and accessing system 100 according to the present invention. As shown in FIG. 1, the faulty storage area marking and accessing system 100 is applied to a data storage unit 20 having a plurality of storage areas, such as an embedded memory integrated in a SoC 10 (e.g. a cache memory), an external memory (e.g. a flash memory) or any other data storage device. The faulty storage area marking and accessing system 100 provides the data storage unit 20 with an automatic faulty storage area marking function for access control so as to identify faulty and operable storage areas of the data storage unit 20. Thereby, when an external client unit or an internal client unit (e.g. an internal microprocessor 30) wishes to access the data storage unit 20, the faulty storage areas of the data storage unit 20 are avoided being accessed, and only the operable storage areas of the data storage unit 20 are accessed.

As shown in FIG. 1, the faulty storage area marking and accessing system 100 comprises a storage area inspecting module 110, a storage area recording module 120, and an access managing and controlling module 130. In the present embodiment, both the faulty storage area marking and accessing system 100 and the data storage unit 20 can be integrated into the SoC 10.

The storage area inspecting module 110 is used to respond to an inspecting startup event 201 and perform a storage area inspecting process on all the storage areas of the data storage unit 20 so as to inspect whether each of the storage areas is in an operable or faulty status, that is, to identify faulty storage areas and operable storage areas of the data storage unit 20 and acquire addresses of the faulty storage areas. In the present embodiment, the inspecting startup event 201 can be induced by a power-on event of the SoC 10, a reset event of the SoC 10, or a predefined startup signal of the SoC 10 issued after the SoC 10 is idle for a predefined time, etc.

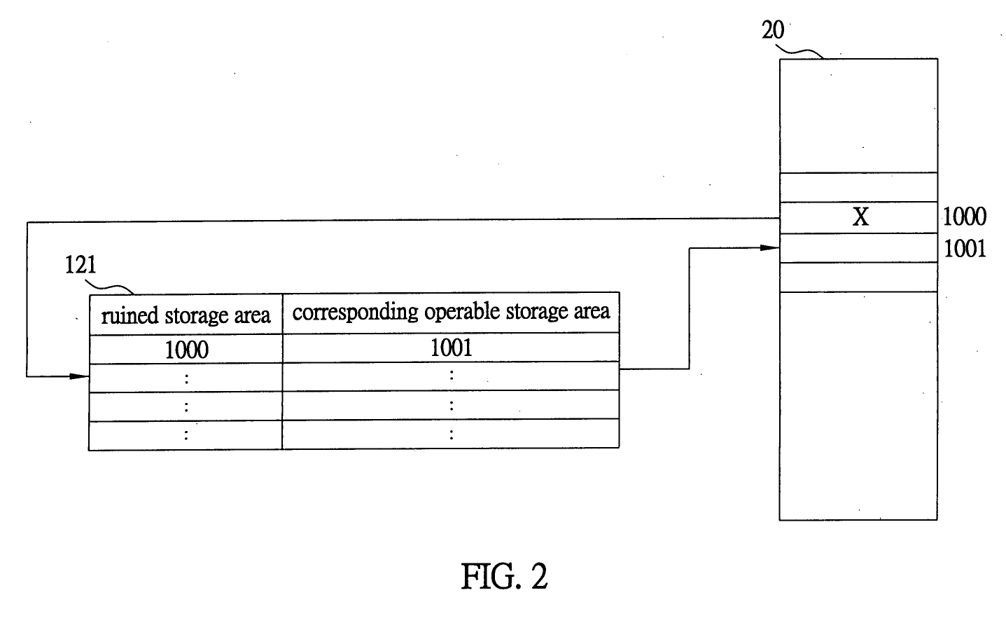

The storage area recording module 120 is used to record the operable or faulty status of each of the storage areas of the data storage unit 20 as inspected by the storage area inspecting module 110 and set up a predefined address assigning rule for assigning an address of each of the faulty storage areas to one of addresses of the operable storage areas. The predefined address assigning rule comprises an address mapping table 121 as shown in FIG. 2 for mapping the addresses of the faulty storage areas to the addresses of the operable storage areas. In the present embodiment, the address mapping table 121 of the storage area recording module 120 comprises a faulty storage area table and an operable storage area table. The operable storage area table stores addresses of the operable storage areas, and the faulty storage area table stores addresses of the faulty storage areas of the data storage unit 20. For instance, if a storage area having an address [1000] of the data storage unit 20 is faulty and another storage area having an address [1001] is operable, the storage area recording module 120 records the address [1000] into the address mapping table 121 and assigns the address [1000] of the faulty storage area to one of the addresses of the operable storage areas, such as [1001].

In addition to an embedded memory, the data storage unit can further comprise an external memory. Accordingly, the predefined address assigning rule can further be used for assigning the addresses of the faulty storage areas of the embedded memory to the addresses of the operable storage areas of the external memory.

The access managing and controlling module 130 is used to receive a request message containing access addresses issued by an external client unit or an internal client unit (e.g. a microprocessor 30 in the SoC 10) to the data storage unit 20, and inspect whether the access addresses of the request message match any address corresponding to the faulty storage areas. If no, that is, all the access addresses of the request message correspond to the operable storage areas, the access managing and controlling module 130 allows the storage area unit 20 to be accessed according to the received access addresses. If yes, that is, at least one of the access addresses corresponds to the faulty storage areas, the access managing and controlling module 130 changes the at least one access address to at least one of the addresses of the operable storage areas in accordance with the address mapping table 121 of the storage area recording module 120, such that the operable storage areas of the data storage unit 20 can be accessed according to the at least one changed address and the other access addresses corresponding to the operable storage areas. If the data storage unit 20 is a cache memory and the access addresses of the request message include at least one address corresponding to the faulty storage areas, the access managing and controlling module 130 responsively issues a miss signal. For example, if the access addresses requested by the microprocessor 30 include an address [1000] corresponding to one of the faulty storage areas, the access managing and controlling module 130 changes the address [1000] to an address [1001] according to the address mapping table 121 in FIG. 2 where address [1000] has been assigned to address [1001], so as to allow the operable storage area of the address [1001] to be accessed in place of the faulty storage area of the address [1000]. Accordingly, the faulty storage area of the address [1000] is avoided being accessed.

Referring to FIGS. 1 and 2, the SoC 10 can be preset to issue an inspecting startup event 201 automatically in response to a power-on event of the SoC 10, a reset event of the SoC 10, or a predefined startup signal of the SoC 10 issued after the SoC 10 is idle for a predefined time. Accordingly, the storage area inspecting module 110 of the faulty storage area marking and accessing system 100 performs a storage area inspecting process on the data storage unit 20 to inspect whether each of the storage areas of the data storage unit 20 is in an operable or faulty status, that is to identify operable storage areas and faulty storage areas of the data storage unit 20. If any faulty storage areas are identified, addresses of all the faulty storage areas are acquired. The storage area recording module 120 records addresses of the faulty storage areas and addresses of the operable storage areas and assigns each of the addresses of the faulty storage areas to one of the addresses of the operable storage areas according to the predefined address assigning rule. For instance, if a storage area having an address [1000] of the data storage unit 20 is faulty and another storage area having an address [1001] is operable, the storage area recording module 120 records the address [1000] of the faulty storage area to the address mapping table 121 in FIG. 2 and assigns the address [1000] to one of the addresses of the operable storage areas, such as [1001].

When an external client unit or an internal client unit such as an internal microprocessor 30 wishes to access the data storage unit 20, access addresses requested by the microprocessor 30 are firstly transmitted to the access managing and controlling module 130 where the access addresses are inspected to match any address corresponding to the faulty storage areas or not. If no, the access managing and controlling module 130 allows the microprocessor 30 to access the data storage unit 20 according to the requested access addresses. If yes, for example, the access addresses include an address [ 1000] corresponding to the faulty storage area, the access managing and controlling module 130 changes the address [1000] to an address [1001] of the operable storage area according to the address mapping table 121 (the predefined address assigning rule) in FIG. 2, such that the microprocessor 30 can access the operable storage area of the address [1001] and the faulty storage area of the address [1000] is avoided being accessed.

Therefore, by applying the faulty storage area marking and accessing method and system to the data storage unit (such as an embedded memory of a SoC), the automatic faulty storage area marking function for access control is provided for the data storage unit. The storage area inspecting process is performed on the data storage unit to inspect the operable or faulty status of each of the storage areas in the data storage unit to identify operable storage areas and faulty storage areas of the data storage unit. Thereby, when a client unit wishes to access the data storage unit, the faulty storage areas are avoided being accessed and only the operable storage areas are accessed. This feature allows the SoC to still operate properly even if the embedded memory thereof has faulty storage areas, without having to replace the entire SoC. Therefore, the present invention overcomes the drawbacks in the prior art without causing a cost issue. Furthermore, the predefined address assigning rule is further a cache miss response to CPU if the embedded memory is a cache memory.

The foregoing descriptions are only the preferred embodiment and not restrictive of the technical scope of the present invention. The essential technical contents of the present invention are widely defined in the appended claims. All embodiments or methods accomplished by others which are the same as the definitions of the following claims or other equivalents should be considered as falling within the scope of the claims.

What is claimed is:

1. A faulty storage area marking and accessing method applicable to a data storage unit having a plurality of storage areas, for providing the data storage unit with an automatic faulty storage area marking function for access control, the faulty storage area marking and accessing method comprising the steps of:
performing a storage area inspecting process on the data storage unit to inspect whether each of the storage areas is in an operable or faulty status to identify operable storage areas and faulty storage areas of the data storage unit in response to receiving an inspecting startup event;
recording the inspected operable or faulty status of each of the storage areas of the data storage unit, and assigning addresses of the faulty storage areas to addresses of the operable storage areas of the data storage unit in accordance with a predefined address assigning rule;
inspecting whether access addresses contained in a request message issued by a client unit to the data storage unit match any address corresponding to the faulty storage areas when the client unit issues the request message to the data storage unit, and if at least one of the access address is inspected to correspond to the faulty storage areas, changing the at least one access address to at least one of the addresses of the operable storage areas in accordance with the predefined address assigning rule; and
accessing the operable storage areas of the data storage unit in place of the faulty storage areas.

2. The faulty storage area marking and accessing method of claim 1, wherein the data storage unit is an embedded memory integrated in a system on chip (SoC).

3. The faulty storage area marking and accessing method of claim 2, wherein the inspecting startup event is induced by a power-on event of the SoC.

4. The faulty storage area marking and accessing method of claim 2, wherein the inspecting startup event is induced by a reset event of the SoC.

5. The faulty storage area marking and accessing method of claim 2, wherein the inspecting startup event is induced by a predefined startup signal of the SoC issued after the SoC is idle for a predefined time.

6. The faulty storage area marking and accessing method of claim 1, wherein the data storage unit comprises an embedded memory.

7. The faulty storage area marking and accessing method of claim 6, wherein the predefined address assigning rule is an address mapping table set up for mapping the addresses of the faulty storage areas to the addresses of the operable storage areas.

8. The faulty storage area marking and accessing method of claim 6, wherein the data storage unit further comprises an external memory, and the predefined address assigning rule assigns the addresses of the faulty storage areas of the embedded memory to the addresses of the operable storage areas of the external memory.

9. The faulty storage area marking and accessing method of claim 8, wherein the embedded memory is a cache memory.

10. The faulty storage area marking and accessing method of claim 9, wherein the predefined address assigning rule is a cache miss response to CPU.

11. A faulty storage area marking and accessing system applicable to a data storage unit having a plurality of storage areas, for providing the data storage unit with an automatic faulty storage area marking function for access control, the faulty storage area marking and accessing system comprising:
a storage area inspecting module for performing a storage area inspecting process on the data storage unit to inspect whether each of the storage areas is in an operable or faulty status to identify faulty storage areas and operable storage areas of the storage areas of the data storage unit in response to an inspecting startup event;
a storage area recording module for recording the inspected operable or faulty status of each of the storage areas of the data storage unit, and assigning addresses of the faulty storage areas to addresses of the operable storage areas in accordance with a predefined address assigning rule; and
an access managing and controlling module for receiving a request message containing access addresses issued by a client unit to the data storage unit and inspecting whether the access addresses of the request message match any address corresponding to the faulty storage areas, wherein if at least one of the access addresses is inspected to correspond to the faulty storage areas, the access managing and controlling module changes the at least one access address to at least one of the addresses of the operable storage areas in accordance with the predefined address assigning rule, so as to allow the operable storage areas of the data storage unit to be accessed in place of the faulty storage areas.

12. The faulty storage area marking and accessing system of claim 11, wherein the data storage unit is an embedded memory integrated in a SoC.

13. The faulty storage area marking and accessing system of claim 11, wherein the inspecting startup event is induced by a power-on event of the SoC.

14. The faulty storage area marking and accessing system of claim 11, wherein the inspecting startup event is induced by a reset event of the SoC.

15. The faulty storage area marking and accessing system of claim 11, wherein the inspecting startup event is induced by a predefined startup signal of the SoC issued after the SoC is idle for a predefined time.

16. The faulty storage area marking and accessing system of claim 11, wherein the data storage unit is an embedded memory.

17. The faulty storage area marking and accessing system of claim 16, wherein the predefined address assigning rule is an address mapping table set up for mapping the addresses of the faulty storage areas to the addresses of the operable storage areas

18. The faulty storage area marking and accessing system of claim 16, wherein the data storage unit further comprises an external memory, and the predefined address assigning rule assigns the addresses of the faulty storage areas of the embedded memory to the addresses of the operable storage areas of the external memory.

19. The faulty storage area marking and accessing system of claim 18, wherein the embedded memory is a cache memory.

20. The faulty storage area marking and accessing system of claim 19, wherein the predefined address assigning rule is a cache miss response to CPU.
